(19) United States
(12) Patent Application Publication
(10) Pub. No.: US 2026/0194588 A1
(43) Pub. Date: Jul. 9, 2026

(54) SYSTEMS AND METHODS FOR BATTERY SOFT SHORT RESISTANCE ESTIMATION

(71) Applicant: GM GLOBAL TECHNOLOGY OPERATIONS LLC, Detroit, MI (US)

(72) Inventors: Xinyu Du, Oakland Township, MI (US); Shengbing Jiang, Rochester Hills, MI (US); Rasoul Salehi, Ann Arbor, MI (US); Shiming Duan, Ann Arbor, MI (US); Chaitanya Sankavaram, Rochester Hills, MI (US); Andrew C. Baughman, Northville, MI (US); Xiumei Guo, Troy, MI (US)

(73) Assignee: GM GLOBAL TECHNOLOGY OPERATIONS LLC, Detroit, MI (US)

(21) Appl. No.: 19/012,694

(22) Filed: Jan. 7, 2025

(51) Int. Cl. G01R 31/389; G01R 31/3828; G01R 31/3842

(52) U.S. Cl. CPC G01R 31/389; G01R 31/3828; G01R 31/3842

(57) ABSTRACT

First battery module charges and second battery module charges are generated by performing an integration of battery module currents with respect to time over first and second time periods. Battery cell group curves associated with the first and second time periods are generated. Each battery cell group curve is representative of a derivative of the cell group voltages of a battery cell group as a function of the battery module charges. Module median curves are generated based on the battery cell group curves. Differences between the battery cell group curve and module median curves are generated. A battery soft short resistance is estimated for a battery cell group based on the change in the charge of the battery module over the first and second time periods, and the voltages and the currents of the battery cell group.

### INTRODUCTION

The technical field generally relates to vehicles, and more particularly relates to systems and methods for battery soft short resistance estimation.

Lithium-ion batteries are typically used in electric vehicles. A decrease in a soft short resistance of a battery may be indicative of degradation of an electrical connection between an anode and a cathode of a battery and may be an early indication of a failure that may lead to an internal hard short. An internal hard short occurs when there is a complete short between the anode and the cathode of the battery.

Accordingly, it is desirable to provide systems and methods for battery soft short resistance estimation to monitor battery health. Other desirable features and characteristics will become apparent from the subsequent detailed description and the appended claims, taken in conjunction with the accompanying drawings and the foregoing technical field and background.

### SUMMARY

A battery soft short resistance estimation system includes at least one processor and at least one memory communicatively coupled to the at least one processor. The at least one memory includes instructions that upon execution by the at least one processor, cause the at least one processor to: receive cell group voltages of a plurality of battery cell groups from a plurality of voltage sensors over first and second time periods; receive cell group currents of the plurality of battery cell groups from a plurality of current sensors over the first and second time periods; generate first battery module charges by performing an integration of the battery module currents with respect to time over a first time range defined by the first time period; generate second battery module charges by performing an integration of the battery module currents with respect to time over a second time range defined by the second time period; generate a first set of battery cell group curves associated with the first time period, each of the first set of battery cell group curves being representative of a derivative of the cell group voltages of an associated battery cell group as a function of the first battery module charges; generate a second set of battery cell group curves associated with the second time period, each of the second set of battery cell group curves being representative of a derivative of the cell group voltages of an associated battery cell group as a function of the second battery module charges; generate a first module median curve associated with the battery module based on the first set of battery cell group curves and a second module median curve associated with the battery module based on the second set of battery cell group curves; generate a first difference between a first battery cell group curve associated with a first one of the plurality of battery cell groups and the first module median curve using an optimization function, the first difference being representative of a first change in a charge of the battery module over the first time period; generate a second difference between the first battery cell group curve associated with the first one of the plurality of battery cell groups and the second module median curve using the optimization function, the second difference being representative of a second change in a charge of the battery module over the second time period; and estimate a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

In at least one embodiment, a time gap between the first period of time and the second period of time is a calibratable time gap range.

In at least one embodiment, the at least one memory further includes instructions that upon execution by the at least one processor, cause the at least one processor to: determine whether a trigger condition has been fulfilled at the first time period and the second time period, the trigger condition being that a battery module current of the battery module is a constant and that a change in a state of charge (SOC) of the battery module is greater than an SOC threshold; and receive the cell group voltages and the cell group currents of the plurality of battery cell groups based on the determination.

In at least one embodiment, the at least one memory further includes instructions that upon execution by the at least one processor, cause the at least one processor to: determine whether the estimated battery soft short resistance for the first one of the plurality of battery cell groups is less than a soft short resistance threshold; and issue a first command to a battery system to shut down the battery module including the first one of the plurality of battery cell groups.

In at least one embodiment, the at least one memory further includes instructions that upon execution by the at least one processor, cause the at least one processor to: determine whether the estimated battery soft short resistance for the first one of the plurality of battery cell groups is less than a soft short resistance threshold; and issue a second command to display a soft short resistance notification associated with the first one of the plurality of battery cell groups based on the determination.

In at least one embodiment, the at least one memory further includes instructions that upon execution by the at least one processor, cause the at least one processor to remove outlier battery soft short resistances associated with the plurality of battery cell groups.

In at least one embodiment, the at least one memory further includes instructions that upon execution by the at least one processor, cause the at least one processor to estimate the battery soft short resistance for the first one of the plurality of battery cell groups based on first differences between module median balance currents associated with the battery module and balance currents associated with the first one of the plurality of battery cell groups over the first time period and second differences between module median balance currents associated with the battery module and balance currents associated with the first one of the plurality of battery cell groups over the second time period.

A method of estimating battery soft short resistance for a battery cell group includes: receiving cell group voltages of a plurality of battery cell groups from a plurality of voltage sensors over first and second time periods; receiving cell group currents of the plurality of battery cell groups from a plurality of current sensors over the first and second time periods; generating first battery module charges by performing an integration of the battery module currents with respect to time over a first time range defined by the first time period; generating second battery module charges by performing an integration of the battery module currents with respect to time over a second time range defined by the second time period; generating a first set of battery cell group curves associated with the first time period, each of the first set of battery cell group curves being representative of a derivative of the cell group voltages of an associated battery cell group as a function of the first battery module charges; generating a second set of battery cell group curves associated with the second time period, each of the second set of battery cell group curves being representative of a derivative of the cell group voltages of an associated battery cell group as a function of the second battery module charges; generating a first module median curve associated with the battery module based on the first set of battery cell group curves and a second module median curve associated with the battery module based on the second set of battery cell group curves; generating a first difference between a first battery cell group curve associated with a first one of the plurality of battery cell groups and the first module median curve using an optimization function, the first difference being representative of a first change in a charge of the battery module over the first time period; generating a second difference between the first battery cell group curve associated with the first one of the plurality of battery cell groups and the second module median curve using the optimization function, the second difference being representative of a second change in a charge of the battery module over the second time period; and estimating a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

In at least one embodiment, a time gap between the first period of time and the second period of time is a calibratable time gap range.

In at least one embodiment, the method further includes: determining whether a trigger condition has been fulfilled at the first time period and the second time period, the trigger condition being that a battery module current of the battery module is a constant and that a change in a state of charge (SOC) of the battery module is greater than an SOC threshold; and receiving the cell group voltages and the cell group currents of the plurality of battery cell groups based on the determination.

In at least one embodiment, the method further includes: determining whether the estimated battery soft short resistance for the first one of the plurality of battery cell groups is less than a soft short resistance threshold; and issuing a first command to a battery system to shut down the battery module including the first one of the plurality of battery cell groups.

In at least one embodiment, the method further includes: determining whether the estimated battery soft short resistance for the first one of the plurality of battery cell groups is less than a soft short resistance threshold; and issuing a second command to display a soft short resistance notification associated with the first one of the plurality of battery cell groups based on the determination.

In at least one embodiment, the method further includes removing outlier battery soft short resistances associated with the plurality of battery cell groups.

In at least one embodiment, the method further includes estimating the battery soft short resistance for the first one of the plurality of battery cell groups based on first differences between module median balance currents associated with the battery module and balance currents associated with the first one of the plurality of battery cell groups over the first time period and second differences between module median balance currents associated with the battery module and balance currents associated with the first one of the plurality of battery cell groups over the second time period.

A vehicle including a battery soft short resistance estimation system includes at least one processor and at least one memory communicatively coupled to the at least one processor. The at least one memory includes instructions that upon execution by the at least one processor, cause the at least one processor to: receive cell group voltages of a plurality of battery cell groups from a plurality of voltage sensors over first and second time periods; receive cell group currents of the plurality of battery cell groups from a plurality of current sensors over the first and second time periods; generate first battery module charges by performing an integration of the battery module currents with respect to time over a first time range defined by the first time period; generate second battery module charges by performing an integration of the battery module currents with respect to time over a second time range defined by the second time period; generate a first set of battery cell group curves associated with the first time period, each of the first set of battery cell group curves being representative of a derivative of the cell group voltages of an associated battery cell group as a function of the first battery module charges; generate a second set of battery cell group curves associated with the second time period, each of the second set of battery cell group curves being representative of a derivative of the cell group voltages of an associated battery cell group as a function of the second battery module charges; generate a first module median curve associated with the battery module based on the first set of battery cell group curves and a second module median curve associated with the battery module based on the second set of battery cell group curves; generate a first difference between a first battery cell group curve associated with a first one of the plurality of battery cell groups and the first module median curve using an optimization function, the first difference being representative of a first change in a charge of the battery module over the first time period; generate a second difference between the first battery cell group curve associated with the first one of the plurality of battery cell groups and the second module median curve using the optimization function, the second difference being representative of a second change in a charge of the battery module over the second time period; and estimate a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

In at least one embodiment, a time gap between the first period of time and the second period of time is a calibratable range.

In at least one embodiment, the at least one memory further includes instructions that upon execution by the at least one processor, cause the at least one processor to: determine whether a trigger condition has been fulfilled at the first time period and the second time period, the trigger condition being that a battery module current of the battery module is a constant and that a change in a state of charge (SOC) of the battery module is greater than an SOC threshold; and receive the cell group voltages and the cell group currents of the plurality of battery cell groups based on the determination.

In at least one embodiment, the at least one memory further includes instructions that upon execution by the at least one processor, cause the at least one processor to: determine whether the estimated battery soft short resistance for the first one of the plurality of battery cell groups is less than a soft short resistance threshold; and issue a first command to a battery system to shut down the battery module including the first one of the plurality of battery cell groups.

In at least one embodiment, the at least one memory further includes instructions that upon execution by the at least one processor, cause the at least one processor to: determine whether the estimated battery soft short resistance for the first one of the plurality of battery cell groups is less than a soft short resistance threshold; and issue a second command to display a soft short resistance notification associated with the first one of the plurality of battery cell groups based on the determination.

In at least one embodiment, the at least one memory further includes instructions that upon execution by the at least one processor, cause the at least one processor to remove outlier battery soft short resistances associated with the plurality of battery cell groups.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a vehicle including a battery soft short resistance estimation system in accordance with at least one embodiment;

FIG. 2 is a functional block diagram of a controller including a battery soft short resistance estimation system in accordance with at least one embodiment;

FIG. 3 is a diagrammatic representation of a battery cell group in accordance with at least one embodiment;

FIG. 4 is a flowchart representation of a method of estimating battery cell group charge change ΔQᵢ for a battery cell group i in a battery module in accordance with at least one embodiment;

FIG. 5 is a graphical representation of a difference between a module median dV/dQ curve for a battery module and a dV/dQ curve for a battery cell group in the battery module in accordance with at least one embodiment

FIG. 6 is a flowchart representation of a method of estimating battery soft short resistance for a battery cell group in accordance with at least one embodiment.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description. As used herein, the term module refers to an application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present disclosure may be practiced in conjunction with any number of systems, and that the systems described herein is merely exemplary embodiments of the present disclosure.

For the sake of brevity, conventional techniques related to signal processing, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

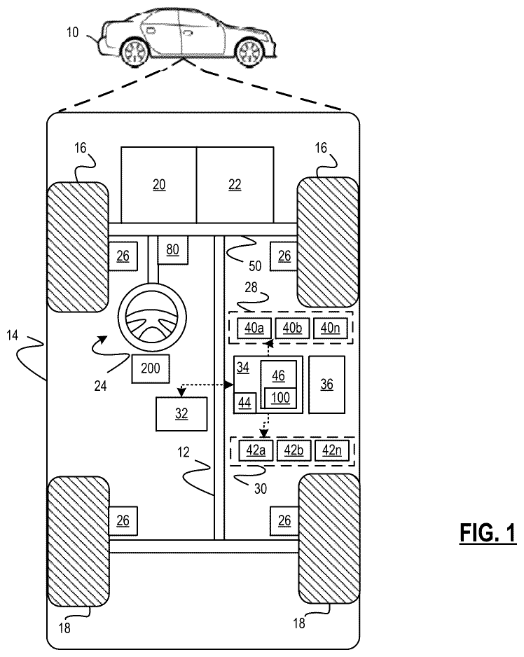

Referring to FIG. 1, a functional block diagram of a vehicle including a battery soft short resistance estimation system 100 in accordance with at least one embodiment is shown. The vehicle 10 generally includes a chassis 12, a body 14, front wheels 16, and rear wheels 18. While the vehicle 10 is depicted in the illustrated embodiment as a passenger car, the vehicle 10 may be other types of vehicles including trucks, sport utility vehicles (SUVs), and recreational vehicles (RVs).

In various embodiments, the body 14 is arranged on the chassis 12 and substantially encloses components of the vehicle 10. The body 14 and the chassis 12 may jointly form a frame. The wheels 16, 18 are each rotationally coupled to the chassis 12 near a respective corner of the body 14.

In various embodiments, the vehicle 10 is an autonomous or semi-autonomous vehicle that is automatically controlled to carry passengers and/or cargo from one place to another. For example, in an exemplary embodiment, the vehicle 10 is a so-called Level Two, Level Three, Level Four or Level Five automation system. Level two automation means the vehicle assists the driver in various driving tasks with driver supervision. Level three automation means the vehicle can take over all driving functions under certain circumstances. All major functions are automated, including braking, steering, and acceleration. At this level, the driver can fully disengage until the vehicle tells the driver otherwise. A Level Four system indicates “high automation”, referring to the driving mode-specific performance by an automated driving system of all aspects of the dynamic driving task, even if a human driver does not respond appropriately to a request to intervene. A Level Five system indicates “full automation”, referring to the full-time performance by an automated driving system of all aspects of the dynamic driving task under all roadway and environmental conditions that can be managed by a human driver.

As shown, the vehicle 10 generally includes a propulsion system 20 a transmission system 22, a steering system 24, a braking system 26, a sensor system 28, an actuator system 30, at least one data storage device 32, at least one controller 34, and a communication system 36. The controller 34 is configured to implement an automated driving system (ADS). The propulsion system 20 is configured to generate power to propel the vehicle. The propulsion system 20 may, in various embodiments, include an internal combustion engine, an electric machine such as a traction motor, a fuel cell propulsion system, and/or any other type of propulsion configuration. The transmission system 22 is configured to transmit power from the propulsion system 20 to the vehicle wheels 16, 18 according to selectable speed ratios. According to various embodiments, the transmission system 22 may include a step-ratio automatic transmission, a continuously-variable transmission, or other appropriate transmission. The braking system 26 is configured to provide braking torque to the vehicle wheels 16, 18. The braking system 26 may, in various embodiments, include friction brakes, brake by wire, a regenerative braking system such as an electric machine, and/or other appropriate braking systems.

The steering system 24 is configured to influence a position of the of vehicle wheels 16. While depicted as including a steering wheel and steering column, for illustrative purposes, in some embodiments contemplated within the scope of the present disclosure, the steering system 24 may not include a steering wheel and/or steering column. The steering system 24 includes a steering column coupled to an axle 50 associated with the front wheels 16 through, for example, a rack and pinion or other mechanism (not shown). Alternatively, the steering system 24 may include a steer by wire system that includes actuators associated with each of the front wheels 16.

The sensor system 28 includes one or more sensing devices 40a-40n that sense observable conditions of the exterior environment and/or the interior environment of the vehicle 10. The sensing devices 40a-40n can include, but are not limited to, radars, lidars, global positioning systems, optical cameras, thermal cameras, ultrasonic sensors, a steering wheel sensor, and/or other sensors.

The vehicle dynamics sensors provide vehicle dynamics data including longitudinal speed, yaw rate, lateral acceleration, longitudinal acceleration, etc. The vehicle dynamics sensors may include wheel sensors that measure information pertaining to one or more wheels of the vehicle 10. In one embodiment, the wheel sensors comprise wheel speed sensors that are coupled to each of the wheels 16, 18 of the vehicle 10. Further, the vehicle dynamics sensors may include one or more accelerometers (provided as part of an Inertial Measurement Unit (IMU)) that measure information pertaining to an acceleration of the vehicle 10. In various embodiments, the accelerometers measure one or more acceleration values for the vehicle 10, including latitudinal and longitudinal acceleration and yaw rate. In at least one embodiment, the vehicle dynamic sensors provide vehicle movement data.

The actuator system 30 includes one or more actuator devices 42a-42n that control one or more vehicle features such as, but not limited to, one or more vehicle wheels 16, 18 the propulsion system 20, the transmission system 22, the steering system 24, and the braking system 26. In various embodiments, the vehicle features can further include interior and/or exterior vehicle features such as, but are not limited to, doors, a trunk, and cabin features such as air, music, lighting, etc. (not numbered).

The communication system 36 is configured to wirelessly communicate information to and from other entities 48, such as but not limited to, other vehicles (“V2V” communication,) infrastructure (“V2I” communication), remote systems, and/or personal devices. In an exemplary embodiment, the communication system 36 is a wireless communication system configured to communicate via a wireless local area network (WLAN) using IEEE 802.11 standards or by using cellular data communication. However, additional, or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards.

The data storage device 32 stores data for use in the ADS of the vehicle 10. In various embodiments, the data storage device 32 stores defined maps of the navigable environment. In various embodiments, the defined maps may be predefined by and obtained from a remote system. For example, the defined maps may be assembled by the remote system and communicated to the vehicle 10 (wirelessly and/or in a wired manner) and stored in the data storage device 32. As can be appreciated, the data storage device 32 may be part of the controller 34, separate from the controller 34, or part of the controller 34 and part of a separate system.

The controller 34 includes at least one processor 44 and a computer readable storage device or media 46. The processor 44 can be any custom made or commercially available processor, a central processing unit (CPU), a graphics processing unit (GPU), an auxiliary processor among several processors associated with the controller 34, a semiconductor-based microprocessor (in the form of a microchip or chip set), a macroprocessor, any combination thereof, or generally any device for executing instructions. The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling the vehicle 10.

The instructions may include one or more separate programs, each of which comprises an ordered listing of executable instructions for implementing logical functions. The instructions, when executed by the processor 44, receive and process signals from the sensor system 28, perform logic, calculations, methods and/or algorithms for automatically controlling the components of the vehicle 10, and generate control signals to the actuator system 30 to automatically control the components of the vehicle 10 based on the logic, calculations, methods, and/or algorithms. Although only one controller 34 is shown in FIG. 1, embodiments of the vehicle 10 can include any number of controllers 34 that communicate over any suitable communication medium or a combination of communication mediums and that cooperate to process the sensor signals, perform logic, calculations, methods, and/or algorithms, and generate control signals to automatically control features of the vehicle 10. In various embodiments, the controller(s) 34 are configured to implement ADS.

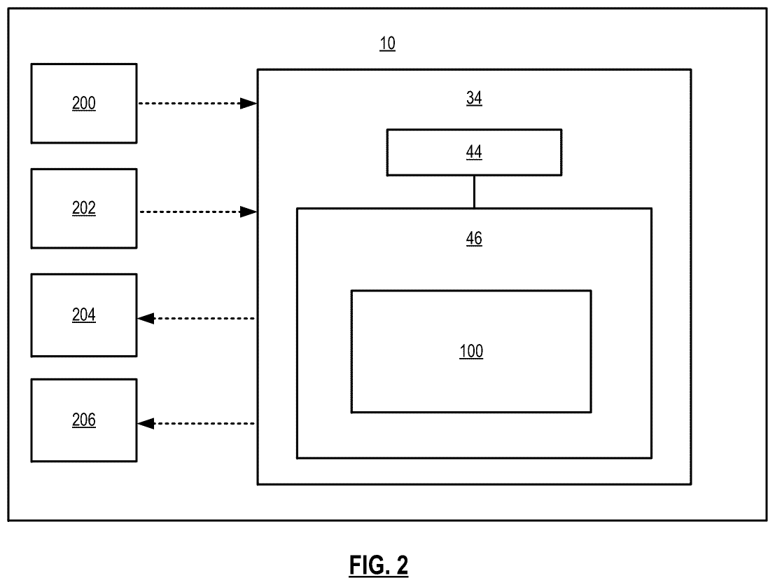

Referring to FIG. 2, a functional block diagram of a controller 34 including a battery soft short resistance estimation system 100 in accordance with at least one embodiment is shown. The controller 34 includes at least one processor 44 and at least one memory 46. The at least one processor 44 is a programable device that includes one or more instructions stored in or associated with the at least one memory 46. The at least one memory 46 includes instructions that the at least one processor 44 is configured to execute. The at least one memory 46 includes an embodiment of the battery soft short resistance estimation system 100.

The controller 34 is configured to be communicatively coupled to at least one voltage sensor 200, at least one current sensor 202, at least one display device 204 and a battery system 206. The battery system 206 includes a plurality of battery modules. Each battery module includes a plurality of battery cell groups. The voltage sensors 200 are configured to detect cell group voltage associated with each of the battery cell groups. The current sensors 202 are configured to detect cell group current associated with each of the battery cell groups. In at least one embodiment the battery cell groups are connected in series. In at least one embodiment, the battery cell groups are connected in series in a battery module. The battery module current of the battery module is equal to the cell group current of the battery cell groups in the battery module.

The battery soft short resistance estimation system 100 is configured to estimate soft short resistances associated with the battery cell groups in a battery module based on the cell group voltages of the battery cell groups and the battery module current. In at least one embodiment, if the battery soft short resistance estimation system 100 determines that an estimated soft short resistance of a battery cell group in the battery module is less than a soft short resistance threshold, the battery soft short resistance estimation system 100 is configured to generate a battery soft short resistance notification associated with that battery cell group for display on the display device 204. In at least one embodiment, if the battery soft short resistance estimation system 100 determines that an estimated soft short resistance of a battery cell group in the battery module is less than a soft short resistance threshold, the battery soft short resistance estimation system 100 is configured to issue a service notification to bring the vehicle 10 to a service center to repair or replace the battery. In at least one embodiment, if the battery soft short resistance estimation system 100 determines that an estimated soft short resistance of a battery cell group in the battery module is less than the soft short resistance threshold, the battery soft short resistance estimation system 100 is configured to issue a command to the battery system 206 to shut down the battery cell group with the estimated soft short resistance that is less than the soft short resistance threshold.

The controller 34 shown in FIG. 2 may include additional components that facilitate operation of the battery soft short resistance estimation system 100. The operation of the battery soft short resistance estimation system 100 will be described in greater detail below.

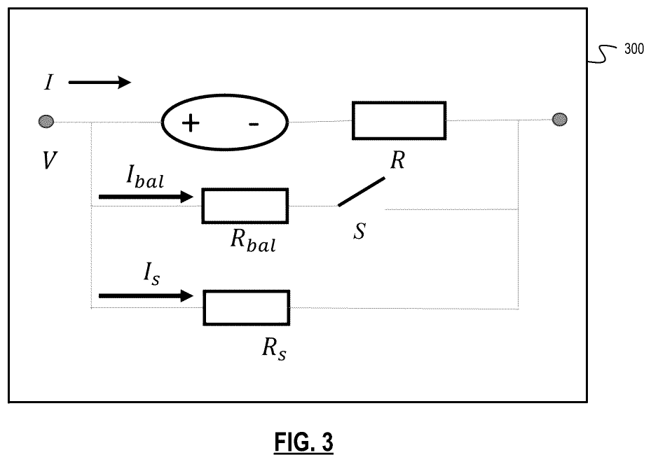

Referring to FIG. 3, a diagrammatic representation of a battery cell group 300 in accordance with at least one embodiment is shown. The battery cell group 300 has a cell group voltage V that can be measured by a voltage sensor 200 and a cell group current I that can be measured by a current sensor 202. The battery soft short resistance estimation system 100 is configured to receive the battery cell group voltages V of the battery cell groups 300 in a battery module and the battery cell group currents I of the battery cell groups 300 in the battery module.

The battery cell groups 300 are connected in series in the battery module. The battery module current I of the battery module that includes the battery cell group 300 is equal to the cell group current I of the battery cell group 300.

The battery cell group 300 includes a balance circuit that includes a balance resistor R_{bal} and a switch S. The switch S is placed in a default open position. It is desirable to maintain the open circuit voltages OCVs of the battery cell groups 300 at similar values. When the OCV of a battery cell group 300 in a battery module deviates from the OCVs of the other battery cell groups in the battery module, the balance circuit is used to actively discharge the battery cell group 300 by closing the switch S and enabling the flow of balance current I_{bal} through the balance circuit. The balance current I_{bal} can be measured by a current sensor 202.

Each battery cell group 300 in the battery module is associated with a soft short resistance R_{S} and a leakage current I_{S} associated with the soft short resistance R_{S}. In a healthy battery cell group 300, the value of the soft short resistance R_{S} is very high, such as for example thousands of ohms and the value of the leakage current I_{S} is very low. As the value of the leakage current I_{S} increases, the value of the soft short resistance R_{S} drops. When the value of the soft short resistance R_{S} associated with a battery cell group 300 falls below a soft short resistance threshold, it may be an early indication of a failure that may lead to an internal hard short. The battery soft short resistance estimation system 100 is configured to estimate the soft short resistances R_{S} of the battery cell groups 300 in the battery module based on the measured battery cell group voltages V of the battery cell groups 300 in the battery module and the measured battery cell group currents I of the battery cell groups 300 in the battery module.

A battery cell group charge change Qᵢ(tₖ₊₁)−Qᵢ(tₖ) of a battery cell group 300 between a time k and k+1 can be represented by a first equation below. The battery cell group in the battery module is represented i.

$${Q}_{i} ( {t}_{k + 1} ) - {Q}_{i} ( {t}_{k} ) = {\int }_{{t}_{k}}^{{t}_{k + 1}} Idt - {\int }_{{t}_{k}}^{{t}_{k + 1}} {I}_{bal}^{i} d t - {\int }_{{t}_{k}}^{{t}_{k + 1}} {V}_{i} d t * \frac{1}{{R}_{s}^{i}}$$

The battery cell group usage is represented by

$${\int }_{{t}_{k}}^{{t}_{k + 1}} Idt ,$$

where I is the measured cell group current. The battery cell group balance charge is represented by

$${\int }_{{t}_{k}}^{{t}_{k + 1}} {I}_{bal}^{i} d t ,$$

where I_{bal} is the flow of balance current through the balance circuit. The battery cell group short charge is

$${\int }_{{t}_{k}}^{{t}_{k + 1}} {V}_{i} d t * \frac{1}{{R}_{s}^{i}} ,$$

where Vᵢ is the measured cell group voltage of the battery cell group and Rⁱ_{S} is the soft short resistance of the battery cell group. The soft short resistance Rⁱ_{S} of the battery cell group is an unknown variable in the equation. The battery soft short resistance estimation system 100 is configured to estimate the soft short resistance Rⁱ_{S} of the battery cell group. The left side of the equation Qᵢ(tₖ₊₁)−Qᵢ(tₖ) is also unknown, that is why the battery soft short resistance estimation system 100 is configured to estimate ΔQᵢ as described in greater below.

A module median charge change Qᵢ(tₖ₊₁)−Qᵢ(tₖ) of a battery module including the battery cell group 300 between a time k and k+1 can be represented by a second equation below. The battery module in the battery system 206 is represented M. The module median charge change is a median of the battery cell group charge changes of the battery cell groups in the battery module.

$${Q}^{M} ( {t}_{k + 1} ) - {Q}^{M} ( {t}_{k} ) = {\int }_{{t}_{k}}^{{t}_{k + 1}} Idt - {\int }_{{t}_{k}}^{{t}_{k + 1}} {I}_{bal}^{M} d t - {\int }_{{t}_{k}}^{{t}_{k + 1}} {V}^{M} d t * \frac{1}{{R}_{s}^{M}}$$

The module median charge usage is represented by

$${\int }_{{t}_{k}}^{{t}_{k + 1}} Idt ,$$

where I is the measured cell group current. The measured cell group current I corresponds to the battery module current I of the battery module. The module median balance charge is represented by

$${\int }_{{t}_{k}}^{{t}_{k + 1}} {I}_{bal}^{M} dt ,$$

where I^{M}_{bal} is the module median balance current through the balance circuits of the battery cell groups in the battery module. The module median short charge is

$${\int }_{{t}_{k}}^{{t}_{k + 1}} {V}^{M} d t * \frac{1}{{R}_{s}^{M}} ,$$

where V^{M} is the module median of the measured cell group voltages of the battery cell groups 300 in the battery module and R^{M}_{S} is the module median of the soft short resistances of the battery cell groups in the battery module. The only unknown variable in the equation is the module median of the soft short resistances R^{M}_{S} of the battery cell groups 300 in the battery module.

The second equation is subtracted from the first equation. The battery cell group usage

$${\int }_{{t}_{k}}^{{t}_{k + 1}} Idt$$

cancels the module median charge usage

$${\int }_{{t}_{k}}^{{t}_{k + 1}} Idt$$

upon the subtraction of the second equation from the first equation. A first assumption is made that V^{M} and Vᵢ have similar values and a second assumption is made that 1/R^{M}_{S} is equal to zero. The second assumption is based on an assumption that almost all of the battery cell groups in the battery module are healthy battery cell groups having high short resistances that can be approximated as an infinite resistance. In addition, Q_{M}−Qᵢ is replaced with ΔQᵢ. The subtracted second equation from the first equation incorporating the described assumptions is rearranged to generate the third equation below from the perspective of the soft short resistance Rⁱ_{S} of the battery cell group.

$${R}_{s}^{i} \approx \frac{\frac{{V}_{i} ( {t}_{k} ) + {V}_{i} ( {t}_{k + 1} )}{2} * ( {t}_{k + 1} - {t}_{k} )}{\begin{matrix}( {Δ}_{{Q}_{i}} ( {t}_{k + 1} ) - {Δ}_{{Q}_{i}} ( {t}_{k} ) ) + \\ ( {CBAhr}^{M} ( {t}_{k + 1} ) - {CBAhr}_{i} ( {t}_{k + 1} ) ) - ( {CBAhr}^{M} ( {t}_{k} ) - {CBAhr}_{i} ( {t}_{k} ) )\end{matrix}} where ,$$

$$( {CBAhr}^{M} ( {t}_{k + 1} ) - {cBAhr}_{i} ( {t}_{k + 1} ) ) - ( {CBAhr}^{M} ( {t}_{k} ) - {cBAhr}_{i} ( {t}_{k} ) ) represents$$

$$[ {\int }_{{t}_{k}}^{{t}_{k + 1}} {I}_{bal}^{i} dt - {\int }_{{t}_{k}}^{{t}_{k + 1}} {I}_{bal}^{M} dt ] .$$

The battery soft short resistance estimation system 100 is configured to estimate the battery cell group charge change ΔQᵢ for each battery cell group i in the battery module and estimate the soft short resistance Rⁱ_{S} for the battery cell group i based on the associated battery cell group charge change ΔQᵢ. The battery soft short resistance estimation system 100 is configured to estimate the battery cell group charge change ΔQᵢ for each battery cell group i based on measured the cell group voltages and the measures cell group currents over a first time period.

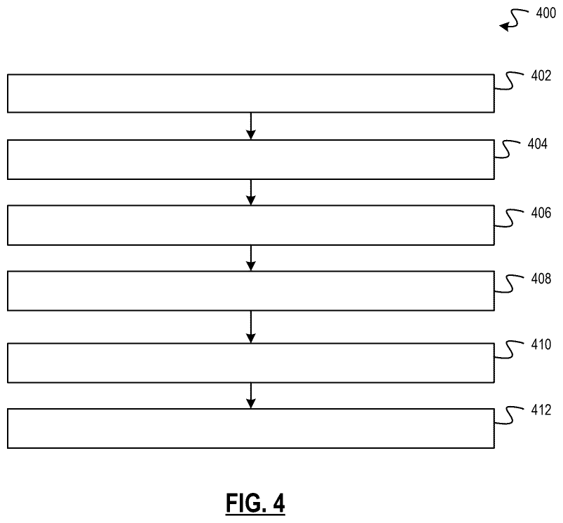

Referring to FIG. 4, a flowchart representation of a method 400 of estimating battery cell group charge change ΔQᵢ for a battery cell group i in a battery module in accordance with at least one embodiment is shown. The method 400 will be described with reference to an exemplary implementation of an embodiment of a battery soft short resistance estimation system 100. As can be appreciated in light of the disclosure, the order of operation within the method 400 is not limited to the sequential execution as illustrated in FIG. 4 but may be performed in one or more varying orders as applicable and in accordance with the present disclosure.

At 402, the battery soft short resistance estimation system 100 receives cell group voltages V and cell group currents I associated with each of the battery cell groups in a battery module over a first time period in response to a trigger condition being fulfilled. The values of the cell group currents I is the same as the value of the battery module current I of the battery module. The trigger condition is that battery module current I is a constant and a change in the state of charge (SOC) of the battery module is greater than a SOC threshold. In at least one embodiment, the trigger condition is that the current I is greater than 75 amps and the SOC threshold is greater than 5%. In alternative embodiments, the trigger condition may be that the current I is greater than a different value and the SOC range of the battery module has a different percentage value. The battery soft short resistance estimation system 100 receives the cell group voltages V from the voltage sensors 200 and cell group currents I from the current sensors 202.

At 404, the battery soft short resistance estimation system 100 generates battery cell group charges Qᵢ is by performing an integration of the battery module currents I with respect to time over a first time range defined by the first time period.

At 406, the battery soft short resistance estimation system 100 generates a battery cell group curve for each of the battery cell groups. In at least one embodiment, the battery soft short resistance estimation system 100 generates a battery cell group curve representative of the derivative of the measured cell group voltages for each of the battery cell groups as a function of the charge Q (dV/dQ) associated with the first time period. In at least one embodiment, the battery soft short resistance estimation system 100 generates a voltage V versus charge Q battery cell group curve for each battery cell group. In at least one embodiment, the battery soft short resistance estimation system 100 generates a change in charge Q as a function of voltage V (represented as dQ/dV) versus charge Q battery cell group curve for each battery cell group. In alternative embodiments, other types of battery cell group curves can be generated.

At 408, the battery soft short resistance estimation system 100 generates a module median curve associated with the battery module based on the battery cell group curves associated with each of the battery cell groups in the battery module. The battery soft short resistance estimation system 100 performs smoothing of the battery cell group curves using a low pass filter and outlier removal.

At 410, the battery soft short resistance estimation system 100 generates a ΔQᵢ for each battery cell group i. In at least one embodiment, the battery soft short resistance estimation system 100 uses an optimization function to search the ΔQᵢ as a function of time to minimize differences between each of the battery cell group curves and the module median curve. The ΔQᵢ for a battery cell group i is the optimization result associated with minimizing the difference between the battery cell group curve of the battery cell group i and the module median curve.

At 412, the ΔQᵢ for each of the battery cell groups associated with the first time period is stored at a data buffer at the battery soft short resistance estimation system 100. The differences ΔCBAhr between the module median balance charge and the battery cell group balance charge for each of the battery cell groups for the first time period are stored in the data buffer at the battery soft short resistance estimation system 100. ΔCBAhr is the difference between cell balance amphrs and module median balance amphrs at a timestep. The battery cell group voltages for each of the battery cell groups for the first time period are stored at the data buffer at the battery soft short resistance estimation system 100.

The method 400 is repeated over several time periods. The ΔQᵢ for each of the battery cell groups, the differences ΔCBAhr between the module median balance charge and the battery cell group balance charge for each of the battery cell groups, and the battery cell group voltages for each of the battery cell groups for each time period are stored at the data buffer at the battery soft short resistance estimation system 100. In at least one embodiment, the method 400 is repeated at least two times over two different periods of time. The battery soft short resistance data for each period of time includes the ΔQᵢ for each of the battery cell groups, the differences ΔCBAhr between the module median balance charge and the battery cell group balance charge for each of the battery cell groups, and the battery cell group voltages for each of the battery cell groups.

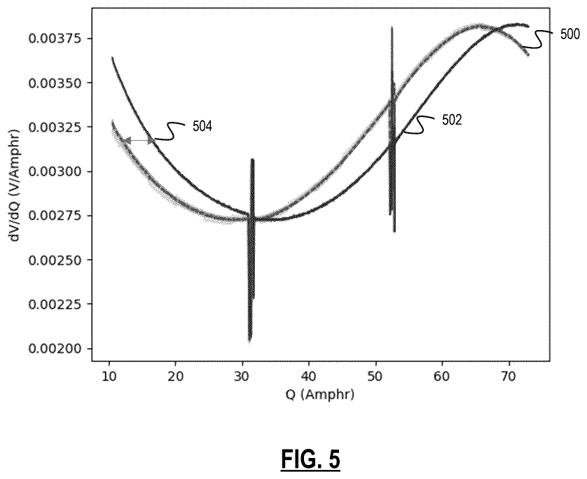

Referring to FIG. 5, a graphical representation of a difference between a module median dV/dQ curve 500 for a battery module and a dV/dQ curve for a battery cell group 502 in the battery module in accordance with at least one embodiment is shown. The difference 504 represents the estimate for the ΔQᵢ associated with the first time period k for the battery cell group i.

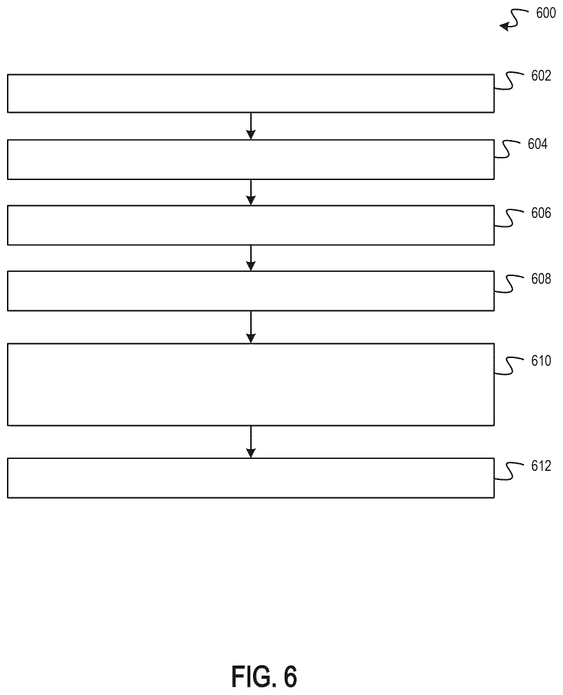

FIG. 6 is a flowchart representation of a method 600 of estimating battery soft short resistance R_{S} for a battery cell group i in accordance with at least one embodiment.

At 602, the battery soft short resistance estimation system 100 retrieves first battery soft short resistance data associated with a first time period and second battery soft short resistance data associated with a second time period for each of the battery cell groups in a battery module from the data buffer where a difference between the first time period and the second time period falls within a range of eight to thirty days. In at least one embodiment, a difference between the first time period and the second time period falls within a calibratable time gap range.

At 604, the battery soft short resistance estimation system 100 calculates an estimated battery soft short resistance R_{S} for each battery cell group i in the battery module using the previously discussed third equation from the perspective of the soft short resistance Rⁱ_{S} of the battery cell group. The third equation has been reproduced below.

$${R}_{s}^{i} \approx \frac{\frac{{V}_{i} ( {t}_{k} ) + {V}_{i} ( {t}_{k + 1} )}{2} * ( {t}_{k + 1} - {t}_{k} )}{\begin{matrix}( {Δ}_{{Q}_{i}} ( {t}_{k + 1} ) - {Δ}_{{Q}_{i}} ( {t}_{k} ) ) + \\ ( {CBAhr}^{M} ( {t}_{k + 1} ) - {CBAhr}_{i} ( {t}_{k + 1} ) ) - ( {CBAhr}^{M} ( {t}_{k} ) - {CBAhr}_{i} ( {t}_{k} ) )\end{matrix}}$$

At 606, the battery soft short resistance estimation system 100 removes outlier values of the soft short resistance Rⁱ_{S} for each time period by comparing each the soft short resistance Rⁱ_{S} in that time period to a median soft short resistance for that time period.

At 608, the battery soft short resistance estimation system 100 calculates a median for the soft short resistances Rⁱ_{S} to generate an estimated soft short resistance Rⁱ_{S} for each of the battery cell groups in the battery module. For each two timesteps k, k+1, one Rⁱ_{S} estimation can be calculated for each battery cell group i. When this calculation is performed more than n times, the median can be used as the final output. For example, if data is collected on day 1, day 7, and day 14, three values of the soft short resistance Rⁱ_{S} can be estimated using data from day 1 and day 7, data from day 1 and day 14, and data from day 7 and day 14. The three values of the soft short resistance Rⁱ_{S} are available on day 14. The median of the three values of the soft short resistance Rⁱ_{S} are generated as the final output for the soft short resistance Rⁱ_{S}.

At 610, the battery soft short resistance estimation system 100 compares the estimated soft short resistance Rⁱ_{S} for each of the battery cell groups in the battery module to a soft short resistance threshold to identify a battery cell group that has an estimated soft short resistance Rⁱ_{S} that is less than the soft short resistance threshold.

At 612, the battery soft short resistance estimation system 100 issues a command to display a soft short resistance notification associated with the identified battery cell group on the display device 204. In at least one embodiment, the battery soft short resistance estimation system 100 issues a command to the battery system 206 to shut down the battery module including identified battery cell group.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A battery soft short resistance estimation system comprising:
at least one processor; and
at least one memory communicatively coupled to the at least one processor, the at least one memory comprising instructions that upon execution by the at least one processor, cause the at least one processor to:
receive cell group voltages of a plurality of battery cell groups from a plurality of voltage sensors over first and second time periods;
receive cell group currents of the plurality of battery cell groups from a plurality of current sensors over the first and second time periods;
generate first battery module charges by performing an integration of the battery module currents with respect to time over a first time range defined by the first time period;
generate second battery module charges by performing an integration of the battery module currents with respect to time over a second time range defined by the second time period;
generate a first set of battery cell group curves associated with the first time period, each of the first set of battery cell group curves being representative of a derivative of the cell group voltages of an associated battery cell group as a function of the first battery module charges;
generate a second set of battery cell group curves associated with the second time period, each of the second set of battery cell group curves being representative of a derivative of the cell group voltages of an associated battery cell group as a function of the second battery module charges;
generate a first module median curve associated with the battery module based on the first set of battery cell group curves and a second module median curve associated with the battery module based on the second set of battery cell group curves;
generate a first difference between a first battery cell group curve associated with a first one of the plurality of battery cell groups and the first module median curve using an optimization function, the first difference being representative of a first change in a charge of the battery module over the first time period;
generate a second difference between the first battery cell group curve associated with the first one of the plurality of battery cell groups and the second module median curve using the optimization function, the second difference being representative of a second change in a charge of the battery module over the second time period; and
estimate a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

2. The system of claim 1, wherein a time gap between the first period of time and the second period of time is a calibratable time gap range.

3. The system of claim 1, wherein the at least one memory further comprises instructions that upon execution by the at least one processor, cause the at least one processor to:
determine whether a trigger condition has been fulfilled at the first time period and the second time period, the trigger condition being that a battery module current of the battery module is a constant and that a change in a state of charge (SOC) of the battery module is greater than an SOC threshold; and
receive the cell group voltages and the cell group currents of the plurality of battery cell groups based on the determination.

4. The system of claim 1, wherein the at least one memory further comprises instructions that upon execution by the at least one processor, cause the at least one processor to:
determine whether the estimated battery soft short resistance for the first one of the plurality of battery cell groups is less than a soft short resistance threshold; and
issue a first command to a battery system to shut down the battery module including the first one of the plurality of battery cell groups.

5. The system of claim 1, wherein the at least one memory further comprises instructions that upon execution by the at least one processor, cause the at least one processor to:
determine whether the estimated battery soft short resistance for the first one of the plurality of battery cell groups is less than a soft short resistance threshold; and
issue a second command to display a soft short resistance notification associated with the first one of the plurality of battery cell groups based on the determination.

6. The system of claim 1, wherein the at least one memory further comprises instructions that upon execution by the at least one processor, cause the at least one processor to remove outlier battery soft short resistances associated with the plurality of battery cell groups.

7. The system of claim 1, wherein the at least one memory further comprises instructions that upon execution by the at least one processor, cause the at least one processor to estimate the battery soft short resistance for the first one of the plurality of battery cell groups based on first differences between module median balance currents associated with the battery module and balance currents associated with the first one of the plurality of battery cell groups over the first time period and second differences between module median balance currents associated with the battery module and balance currents associated with the first one of the plurality of battery cell groups over the second time period.

8. A method of estimating battery soft short resistance for a battery cell group comprising:
receiving cell group voltages of a plurality of battery cell groups from a plurality of voltage sensors over first and second time periods;
receiving cell group currents of the plurality of battery cell groups from a plurality of current sensors over the first and second time periods;
generating first battery module charges by performing an integration of the battery module currents with respect to time over a first time range defined by the first time period;
generating second battery module charges by performing an integration of the battery module currents with respect to time over a second time range defined by the second time period;
generating a first set of battery cell group curves associated with the first time period, each of the first set of battery cell group curves being representative of a derivative of the cell group voltages of an associated battery cell group as a function of the first battery module charges;
generating a second set of battery cell group curves associated with the second time period, each of the second set of battery cell group curves being representative of a derivative of the cell group voltages of an associated battery cell group as a function of the second battery module charges;
generating a first module median curve associated with the battery module based on the first set of battery cell group curves and a second module median curve associated with the battery module based on the second set of battery cell group curves;
generating a first difference between a first battery cell group curve associated with a first one of the plurality of battery cell groups and the first module median curve using an optimization function, the first difference being representative of a first change in a charge of the battery module over the first time period;
generating a second difference between the first battery cell group curve associated with the first one of the plurality of battery cell groups and the second module median curve using the optimization function, the second difference being representative of a second change in a charge of the battery module over the second time period; and
estimating a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

9. The method of claim 8, wherein a time gap between the first period of time and the second period of time is a calibratable time gap range.

10. The method of claim 8, further comprising:
determining whether a trigger condition has been fulfilled at the first time period and the second time period, the trigger condition being that a battery module current of the battery module is a constant and that a change in a state of charge (SOC) of the battery module is greater than an SOC threshold; and
receiving the cell group voltages and the cell group currents of the plurality of battery cell groups based on the determination.

11. The method of claim 8, further comprising:
determining whether the estimated battery soft short resistance for the first one of the plurality of battery cell groups is less than a soft short resistance threshold; and
issuing a first command to a battery system to shut down the battery module including the first one of the plurality of battery cell groups.

12. The method of claim 8, further comprising:
determining whether the estimated battery soft short resistance for the first one of the plurality of battery cell groups is less than a soft short resistance threshold; and
issuing a second command to display a soft short resistance notification associated with the first one of the plurality of battery cell groups based on the determination.

13. The method of claim 8, further comprising removing outlier battery soft short resistances associated with the plurality of battery cell groups.

14. The method of claim 8, further comprising estimating the battery soft short resistance for the first one of the plurality of battery cell groups based on first differences between module median balance currents associated with the battery module and balance currents associated with the first one of the plurality of battery cell groups over the first time period and second differences between module median balance currents associated with the battery module and balance currents associated with the first one of the plurality of battery cell groups over the second time period.

15. A vehicle including a battery soft short resistance estimation system comprising:
at least one processor; and
at least one memory communicatively coupled to the at least one processor, the at least one memory comprising instructions that upon execution by the at least one processor, cause the at least one processor to:
receive cell group voltages of a plurality of battery cell groups from a plurality of voltage sensors over first and second time periods;
receive cell group currents of the plurality of battery cell groups from a plurality of current sensors over the first and second time periods;
generate first battery module charges by performing an integration of the battery module currents with respect to time over a first time range defined by the first time period;
generate second battery module charges by performing an integration of the battery module currents with respect to time over a second time range defined by the second time period;
generate a first set of battery cell group curves associated with the first time period, each of the first set of battery cell group curves being representative of a derivative of the cell group voltages of an associated battery cell group as a function of the first battery module charges;
generate a second set of battery cell group curves associated with the second time period, each of the second set of battery cell group curves being representative of a derivative of the cell group voltages of an associated battery cell group as a function of the second battery module charges;
generate a first module median curve associated with the battery module based on the first set of battery cell group curves and a second module median curve associated with the battery module based on the second set of battery cell group curves;
generate a first difference between a first battery cell group curve associated with a first one of the plurality of battery cell groups and the first module median curve using an optimization function, the first difference being representative of a first change in a charge of the battery module over the first time period;
generate a second difference between the first battery cell group curve associated with the first one of the plurality of battery cell groups and the second module median curve using the optimization function, the second difference being representative of a second change in a charge of the battery module over the second time period; and
estimate a battery soft short resistance for the first one of the plurality of battery cell groups based on the first change in the charge of the battery module over the first time period, the second change in the charge of the battery module over the second time period, the cell group voltages of the first one of the plurality of battery cell groups and the cell group current of the first one of the plurality of battery cell groups.

16. The vehicle of claim 15, wherein a time gap between the first period of time and the second period of time is a calibratable range.

17. The vehicle of claim 15, wherein the at least one memory further comprises instructions that upon execution by the at least one processor, cause the at least one processor to:
determine whether a trigger condition has been fulfilled at the first time period and the second time period, the trigger condition being that a battery module current of the battery module is a constant and that a change in a state of charge (SOC) of the battery module is greater than an SOC threshold; and
receive the cell group voltages and the cell group currents of the plurality of battery cell groups based on the determination.

18. The vehicle of claim 15, wherein the at least one memory further comprises instructions that upon execution by the at least one processor, cause the at least one processor to:
determine whether the estimated battery soft short resistance for the first one of the plurality of battery cell groups is less than a soft short resistance threshold; and
issue a first command to a battery system to shut down the battery module including the first one of the plurality of battery cell groups.

19. The vehicle of claim 15, wherein the at least one memory further comprises instructions that upon execution by the at least one processor, cause the at least one processor to:
determine whether the estimated battery soft short resistance for the first one of the plurality of battery cell groups is less than a soft short resistance threshold; and
issue a second command to display a soft short resistance notification associated with the first one of the plurality of battery cell groups based on the determination.

20. The vehicle of claim 15, wherein the at least one memory further comprises instructions that upon execution by the at least one processor, cause the at least one processor to remove outlier battery soft short resistances associated with the plurality of battery cell groups.
